(19) United States
(12) Patent Application Publication
(10) Pub. No.: US 2025/0076416 A1
(43) Pub. Date: Mar. 6, 2025

(54) TEMPERATURE CONTROL FOR HALL BAR SENSOR CORRECTION

(71) Applicant: Corephotonics Ltd., Tel Aviv (IL)

(72) Inventors: Yiftah Kowal, Tel Aviv (IL); Michael Scherer, Tel Aviv (IL)

(21) Appl. No.: 18/950,238

(22) Filed: Nov. 18, 2024

Related U.S. Application Data
(63) Continuation of application No. 18/320,972, filed on May 20, 2023, now Pat. No. 12,174,272.
Application No. 18/320,972 is a continuation of application No. 17/614,571, filed on Nov. 29, 2021, now Pat. No. 11,693,064.
(60) Provisional application No. 63/015,576, filed on Apr. 26, 2020.

(51) Int. Cl. G01R 33/00; G01D 5/14; H02K 11/215; H02K 41/035; H04M 1/02

(52) U.S. Cl. CPC G01R 33/0082; G01D 5/145; H02K 11/215; H02K 41/0354; H04M 1/026; H04M 2250/12

(57) ABSTRACT

Systems and methods for eliminating or mitigating T-effects on Hall sensors. A system may comprise a magnet-coil arrangement for providing a relative movement therebetween to obtain a relative position, a Hall sensor for sensing the relative movement, a temperature sensor located in proximity of the Hall sensor for providing temperature sensing, and a controller having two or more channels coupled to Hall sensor and to the temperature sensor and configured to control the relative movement and to provide, based on the temperature sensing, a temperature correction input to the Hall sensor for compensating a temperature effect on the Hall sensor sensing.

### CROSS REFERENCE TO RELATED APPLICATIONS

This application is a continuation application of U.S. patent application Ser. No. 18/320,972 filed May 20, 2023 (now allowed), which was a continuation of U.S. patent application Ser. No. 17/614,571 filed Nov. 29, 2021 (now U.S. Pat. No. 11,693,064), which was a 371 application from international patent application PCT/IB2021/052802 filed Apr. 4, 2021, and claims the benefit of U.S. Provisional patent application No. 63/015,576 filed Apr. 26, 2020, which is incorporated herein by reference in its entirety.

### FIELD

Embodiments disclosed herein relate to voice coil motors (VCMs) in small portable electronic devices such as smartphones, tablet computers, laptops etc. and in particular to compensation for the impact of heat (temperature) on sensors measuring movement actuated by such VCMs.

### BACKGROUND

Cameras incorporated in various mobile electronic devices such as smartphones, tablet computers, laptops etc. use miniature, compact actuators for various movements (e.g. rotating, tilting, shifting, etc.) of various elements such as lenses, reflecting elements and others. These actuators are often of a voice coil motor (VCM) or a stepper motor. In particular, VCMs are used for moving lenses for focusing and for moving reflecting elements (in “folded” cameras) and/or lenses for optical image stabilization (OIS). A VCM includes at least one magnet-coil pair. FIG. 1 shows schematically an exemplary VCM numbered 100, comprising a magnet 102, a coil 104 and a Hall bar sensor (or simply “Hall sensor” or “Hall bar”) 106 in (a) top (planar) view and (b) a side (cross section) view. During actuation, controlled through a controller (not shown here), the magnet and coil perform a relative movement therebetween (e.g. in the X direction in the XY plane shown), the movement driven by current passing through the coil. The position of the magnet relative to the coil is measured by the Hall sensor and read by the controller. In some embodiments, the Hall sensor is located within the coil, as in FIG. 1.

The measurement by the Hall sensor is affected by temperature (“T”) changes. Increases in T are caused by the current driven through the coil as well as by heat generated by various components of the camera and/or around the VCM. In a VCM such as 100, a typical T increase at a location within the coil such as the location of Hall sensor 106 may be 10-75 degrees or more. For typical Hall sensors, a T increase of 100 degrees may lead to a decrease in output voltage of 3-10%.

For example, assuming (1) a T increase of 50 degrees, (2) a Hall sensor undergoing an output voltage decrease of 6% for 100 degrees, and (3) a linear behavior of this decrease over the 100 degree range, an output voltage decrease of 3% may be expected. This 3% decrease can pose a significant obstacle for applications such as OIS or autofocusing (AF) a camera, where typically accuracies of a few micrometers (μm) are required for a travel range or “stroke” of 0.3-1 mm.

The T-effect on a Hall sensor position measurement is an unwanted, deleterious effect, affecting in particular the repeatability of the Hall sensor output with respect to magnetic flux. The accuracy in positioning of camera components (such as lenses) actuated by VCMs can be improved if the T-effect on the Hall sensor position measurement is eliminated or at least mitigated.

There is a need for, and it would be advantageous to have elimination or at least mitigation of the T-effect on a Hall sensor in a VCM.

### SUMMARY

In various embodiments, there are provided systems for eliminating or mitigating T-effects on Hall sensors in VCMs, in which a very small temperature sensor (semiconductor diode) that can fit next to a Hall sensor inside the coil and which is coupled electrically to available, unused Hall sensor channels of the MCU that controls the VCM.

In some embodiments, a system may comprise a magnet-coil arrangement for providing a relative movement therebetween to obtain a relative position; a Hall sensor for sensing the relative movement; a temperature sensor located in proximity of the Hall sensor for providing temperature sensing; and a controller having two or more channels coupled to Hall sensor and to the temperature sensor and configured to control the relative movement and to provide, based on the temperature sensing, a temperature correction input to the Hall sensor for compensating (correcting) a temperature effect on the Hall sensor sensing, whereby the corrected Hall sensor sensing can be used to correct the relative position.

In some embodiments, the magnet-coil arrangement may be included in a voice coil-motor. In some embodiments, the magnet-coil arrangement may be included in a stepper motor.

In some embodiments, the controller may be coupled to the temperature sensor through existing unused controller channels. In some embodiments, the Hall sensor may be located within the coil. In some embodiments, both the temperature sensor and the Hall sensor are located within the coil. In some embodiments, the temperature sensor may be a semiconductor diode. In some embodiments, the temperature sensor may be a thermistor.

In some embodiments, the controller may have two channels. In some embodiments, the controller may have three channels. In some embodiments, the controller may have four or more channels.

In some embodiments, the Hall sensor includes a Hall sensor input and a Hall sensor output and the controller includes an interface for operative coupling to the Hall sensor input and output.

In some embodiments, the controller channels interface includes a first Hall sensor channel comprising a first current module coupled to the Hall sensor input and a first voltage sense module coupled to the Hall sensor output and sensing the Hall output voltage, and a second Hall sensor channel comprising a second current module coupled to the temperature sensor and a second voltage sense module coupled to the temperature sensor and sensing the temperature sensor output voltage that is correlated with the temperature.

In some embodiments, the controller may have an area smaller than 25 mm². In some embodiments, the controller may have an area smaller than 20 mm². In some embodiments, the controller may have an area smaller than 15 mm².

In some embodiments, the Hall sensor and the temperature sensor are thermally coupled. In some embodiments, the Hall sensor and the temperature sensor are thermally coupled by a thermal conductive paste.

In some embodiments, the controller may be a standalone component. In some embodiments, the controller may be integrated as a sub-component into another electronic component.

In some embodiments, the temperature sensor may be not located in proximity of the Hall sensor, but at a position that resembles the T environment in close proximity of the Hall sensor.

In various embodiments there may be provided a mobile device comprising a system as above or below.

In some embodiments, the mobile device may be a smartphone.

### BRIEF DESCRIPTION OF THE DRAWINGS

Non-limiting examples of embodiments disclosed herein are described below with reference to figures attached hereto that are listed following this paragraph. Identical structures, elements or parts that appear in more than one figure are generally labeled with a same numeral in all the figures in which they appear. The drawings and descriptions are meant to illuminate and clarify embodiments.

FIG. 1 shows schematically an exemplary VCM in (a) top view and (b) cross section;

FIG. 2 illustrates an embodiment of a system disclosed herein and comprising a Hall sensor, a temperature sensor and a controller;

FIG. 3 illustrates schematically an embodiment of a VCM with T-compensation for Hall sensor sensing drift disclosed herein in (a) top view and (b) cross section;

FIG. 4 illustrates an internal layout of the controller in the system of FIG. 2;

FIG. 5 illustrates in a flow chart an embodiment of a method disclosed herein.

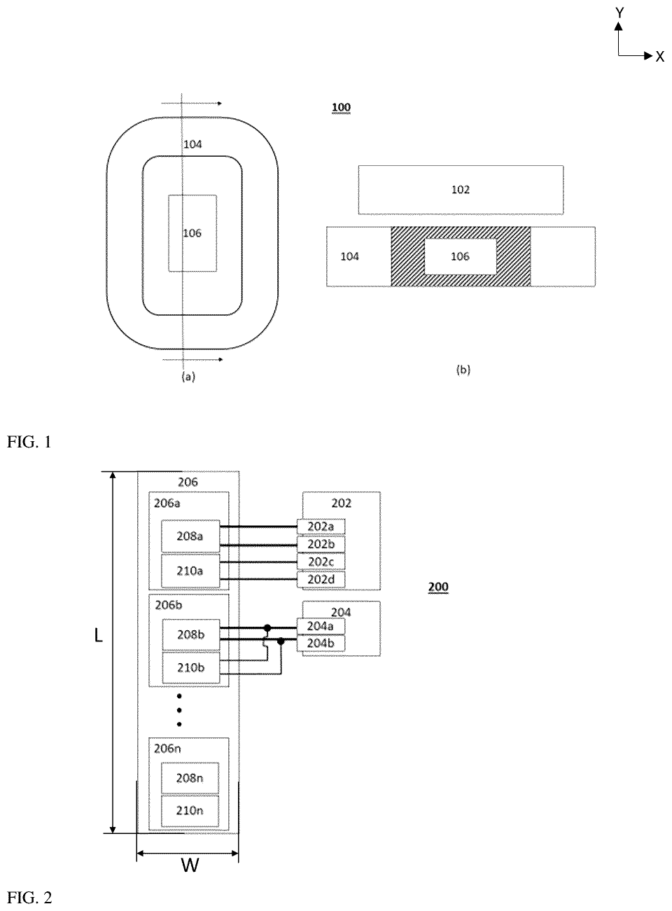

### DETAILED DESCRIPTION

Camera actuator controllers have analog circuitry for connection to a Hall sensor. As indicated above, a Hall sensor channel comprises an input voltage sense and output constant current source. Some camera actuator controllers have spare channels for more Hall sensors, which are not in use (“unused channels”).

Reference is now made to FIG. 2, which illustrates an embodiment of a system 200 comprising a Hall sensor 202, a temperature sensor 204 (“T-sensor”) and a controller (also called “microcontroller” or “MCU”) 206. Controller 206 is for example a VCM controller or a Hall sensor controller used in digital cameras. Controller 206 includes a plurality of sensor channels 206a, 206b . . . 206n. Each sensor channel 206a, 206b . . . 206n includes a respective current module 208a, 208b . . . 208n and a respective voltage sense module 210a, 210b . . . 210n. Applicant has determined that controller 206 may be coupled to T-sensor 204. Hall sensor 202 includes input terminals 202a and 202b, which are current input terminals, and output terminals 202c and 202d, which are voltage output terminals. T-sensor 204 comprises two terminals 204a and 204b, which are current terminals. Current module 208a is coupled to input terminals 202a and 202b and is configured to excite a constant current through input terminals 202a and 202b. Voltage sense module 210a is coupled to output terminals 202c and 202d and is configured to measure the voltage over terminals 202c and 202d. Current module 208b is coupled to terminals 204a and 204b and is configured to excite a constant current through terminals 204a and 204b. In some embodiments, current module 208b may be coupled to terminals 204a and 204b via another electrical component such as a resistor. Voltage sense module 210b is also coupled to terminals 204a and 204b and is configured to sense the voltage over terminals 204a and 204b.

A controller as defined herein may be a standalone component, e.g. an integrated circuit (IC). An IC with a built-in Hall signal processing circuit may be beneficial. Typically and in a top view, such a standalone controller has a substantially quadrangular shape, with its length (“L”) and width (“W”) being substantially larger than its height. Typically, a length×width may be (1-5) mm×(1-5) mm and a height may be (0.3-1) mm, e.g. 4 mm×4 mm×0.75 mm (having an “area” of 16 mm²) or 2 mm×5 mm×0.5 mm (having an area of 10 mm²).

In other embodiments, a controller may be included as a sub-component in another electronic component. The other electronic component may be a controller not only including the channels having a current module and a voltage sense module each, such as channels 206a, . . . 206n, and built-in Hall signal processing circuits, but it may have additional channels with other functionalities. In some embodiments, the other controller may be realized in the application processor (AP) of a mobile electronic device. In other embodiments, the other controller may be realized in the image sensor of a camera included in a mobile electronic device.

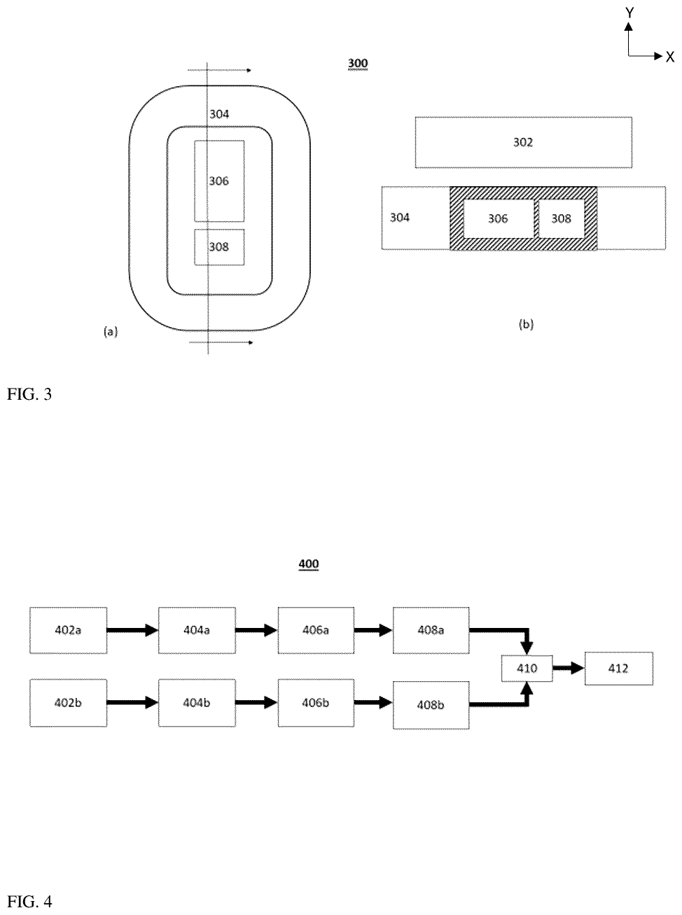

Reference is now made to FIG. 3, which illustrates an embodiment of a VCM with T-compensation for Hall sensor sensing drift disclosed herein and numbered 300. FIG. 3 illustrates in (a) a top (planar) view and in (b) a side (cross section) view of the VCM. VCM 300 includes a magnet 302 and a coil 304. In some embodiments and as shown, a Hall sensor 306 and a T-sensor (e.g. a semiconductor diode serving as a T-sensor) 308 are positioned inside coil 304. In other embodiments, Hall sensor 306 and T-sensor 308 may be positioned outside of a coil such as coil 304. In some embodiments, T-sensor 308 is located in close proximity to Hall sensor 306. In some embodiments, T-sensor 308 may be a thermistor. In other embodiments, T-sensor 308 may be included in a system based on another actuator technology, e.g. a system including a stepper motor.

In some embodiments, it may be beneficial to place the T-sensor as close to the Hall sensor as possible. “As close as possible” may be 1 mm, or even 500 μm or less, e.g. 100 μm.

In other embodiments, especially where a temperature gradient is relatively shallow, the distance between the T-sensor and the Hall sensor may be larger.

In yet other embodiments, a T-sensor may be placed not in close proximity of the Hall bar, but at a location that resembles the T environment which is present in close proximity of the Hall sensor. As an example, assume that one may find that the local T at the Hall sensor location correlates very strongly with a local T at a different position, which may not necessarily be close according to the definition given above.

As an example for such a constellation and with reference to FIG. 3, a Hall sensor may be placed at a position left (in the −x direction) of coil 304, and a T-sensor may be placed at a position right (in the +x direction) of coil 304, so that the center of the Hall sensor and the center of the T-sensor are both located at an identical y-coordinate and that additionally the distance between the Hall sensor and the coil is substantially identical to the distance between the T-sensor and the coil.

In other embodiments, Hall sensor 306 and T-sensor 308 may be thermally coupled. A thermal coupling may be beneficial as it allows sensing the local T at the position of the Hall bar more accurately. A thermal coupling may be achieved by physically coupling Hall sensor 306 and T-sensor 308, e.g. with thermal conductive paste or with some other component exhibiting high thermal conductivity and which physically connects the Hall sensor and the T-sensor.

In some embodiments and e.g. for a more precise measurement of a local T, two or more T-sensors may be included at two or more different positions and coupled to a controller for sensing a temperature at the two or more positions. For estimating a local T, e.g. at the position of the Hall sensor, T values of the two or more T-sensors may be considered, e.g. by averaging the T values or by calculating a weighted sum considering for each T-sensor its T value as well as its distance from to the Hall sensor.

As known, the forward voltage of a diode is approximately proportional to the absolute T. The well-known expression for the (forward bias) diode voltage Vd is as follows:

$$Vd \approx kT / q ln ( Id / Is ) \qquad ( 1 )$$

where Vd=voltage across diode, k=Boltzman contant, T=absolute T, q=electron charge, Id=current through diode and Is=diffusion current. Therefore, a measurement of the diode voltage Vd provides T.

Reference is now made to FIG. 4, which illustrates an embodiment 400 using a controller such as controller 206 for performing a T compensated Hall sensor measurement. Specifically, it is outlined how a controller channel such as 206a, 206b . . . 206n may be used for extracting a T signal from a T-sensor such as 204 for T-compensated Hall sensor sensing.

In many VCMs such as 100, the controller includes a larger number of channels than coupled sensors. For example, referring to VCM 100, the controller may typically include 1-5 channels, and only one Hall sensor such as 106 may be coupled to the controller. For example, assuming a 3-channel controller, from the 3 channels of this controller only one channel is “used”, wherein 2 channels are “unused”. For embodiment 400, a T-sensor such as 204 can be coupled to one of the unused channels.

In other embodiments having two or more unused channels, two or more T-sensors may be coupled to the unused channels.

As shown in FIG. 2, a first T-sensor channel of controller 206 may be coupled to a Hall sensor such as 202, and a second sensor channel may be coupled to a T-sensor such as 204. Each sensor channel includes a current module and a voltage sense module. In the following, consider only the voltage sense modules of each channel, assuming however that the respective current modules excite a constant current output for the sensors.

The internal layout includes two voltage sense modules 402a and 402b, two amplifiers 404a and 404b, two analog-to-digital converters (ADC) 406a and 406b, two variables 408a and 408b, a function for transfer from hardware (HW) to software (SW) 410 and an output 412. As known, a variable is a storage address (identified by a memory address) paired with an associated symbolic name, which contains some known or unknown quantity of information referred to as a value. Voltage sense module 402a may be the same as voltage sense module 210a of FIG. 2 and is coupled electrically to amplifier 404a. Amplifier 404a is coupled electrically to ADC 406a, which outputs variable 408a. Voltage sense module 402b may be the same as voltage sense module 210b of FIG. 2 and is coupled electrically to amplifier 404b. Amplifier 404b is coupled electrically to ADC 406b, which outputs variable 408b. Variables 408a and 408b are inputs to function 410. Variable 408a may represent the voltage measured over the output of a Hall sensor (V_{H}), also referred to as “Hall output voltage signal”. Variable 408b may represent the voltage over the output of a T-sensor that is translatable into a T value used in equation 2 below. Function 410 takes variable 408a and variable 408b and outputs output 412. In an example, the value of output 412 may be an estimation of the (sought after) value of V_{H}0, the factor of the voltage over the output of the Hall sensor that is affected only by magnetic flux and not by T, and a and b are constants. For example:

$${V}_{H} ( B , T ) \approx {V}_{H} 0 ( B ) \times [ 1 + a \times ( T - T 0 ) ] + b \times ( T - T 0 ) \qquad ( 2 )$$

V_{H} is a function of B, the magnetic flux measured by the Hall sensor, and T, the T measured by a T-sensor. T0 is a reference temperature. The values of constant parameters a and b may be supplied by the manufacturer, calculated from the Hall sensor datasheet and/or calculated in a controlled environment experiment.

To summarize, in a method disclosed herein, one uses V_{H} and T (which is related in a known way to Vd) to find V_{H}0.

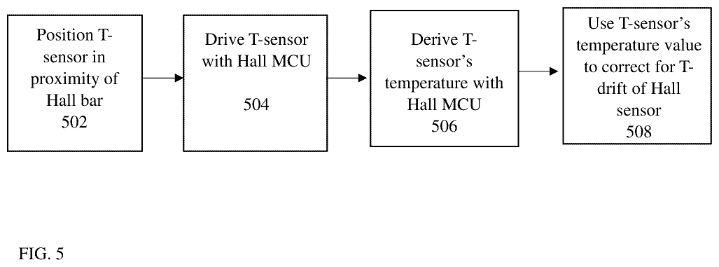

FIG. 5 shows an embodiment of a method of use of system 200. T-sensor 308 is positioned in proximity to Hall sensor 306 as in FIG. 3 in step 502. The T-sensor is driven by MCU 206 in step 504, and its T sensing is obtained in step 506. The value of the T read in step 506 is used to correct for T-drift of the Hall sensor measurement in step 508.

For the sake of clarity the term “substantially” is used herein to imply the possibility of variations in values within an acceptable range. According to one example, the term “substantially” used herein should be interpreted to imply possible variation of up to 10% over or under any specified value. According to another example, the term “substantially” used herein should be interpreted to imply possible variation of up to 5% over or under any specified value. According to a further example, the term “substantially” used herein should be interpreted to imply possible variation of up to 2.5% over or under any specified value.

Unless otherwise stated, the use of the expression “and/or” between the last two members of a list of options for selection indicates that a selection of one or more of the listed options is appropriate and may be made.

It should be understood that where the claims or specification refer to “a” or “an” element, such reference is not to be construed as there being only one of that element.

While this disclosure has been described in terms of certain embodiments and generally associated methods, alterations and permutations of the embodiments and methods will be apparent to those skilled in the art. The disclosure is to be understood as not limited by the specific embodiments described herein, but only by the scope of the appended claims.

What is claimed is:

1. A system, comprising:
a voice coil motor (VCM) comprising a magnet-coil arrangement for providing a relative movement therebetween to obtain a relative position;
a Hall sensor located within the coil for sensing the relative movement;
a temperature sensor located in proximity of the Hall sensor for providing temperature sensing; and
a controller having two or more channels coupled to the VCM, to the Hall sensor and to the temperature sensor and configured to control the relative movement between the magnet and the coil of the VCM and to provide, based on the temperature sensing, a temperature correction input to the Hall sensor for compensating a temperature effect on the Hall sensor sensing of the relative movement,
wherein the Hall sensor includes a Hall sensor input and a Hall sensor output and wherein the controller channels include an interface for operative coupling to the Hall sensor input and output,
wherein the controller channels interface includes a first Hall sensor channel comprising a first current module coupled to the Hall sensor input and a first voltage sense module coupled to the Hall sensor output and sensing the Hall output voltage, and a second Hall sensor channel comprising a second current module coupled to the temperature sensor and a second voltage sense module coupled to the temperature sensor and sensing the temperature sensor output voltage correlated with the temperature,
and wherein the second current module coupled to the temperature sensor and the second voltage sense module coupled to the temperature sensor are electrically coupled together.

2. The system of claim 1, wherein the controller is coupled to the temperature sensor through existing unused controller channels.

3. The system of claim 1, wherein the temperature sensor is located within the coil.

4. The system of claim 1, wherein the temperature sensor is a semiconductor diode.

5. The system of claim 1, wherein the temperature sensor is a thermistor.

6. The system of claim 1, including at least one additional temperature sensor to form a plurality of temperature sensors.

7. The system of claim 6, wherein the temperature correction is based on temperature sensing of at least two of the plurality of temperature sensors.

8. The system of claim 1, wherein the controller has two channels.

9. The system of claim 1, wherein the controller has three channels.

10. The system of claim 1, wherein the controller has four or more channels.

11. The system of claim 1, wherein the controller has a built-in Hall signal processing circuit.

12. The system of claim 1, wherein the controller has an area smaller than 25 mm².

13. The system of claim 1, the controller has an area smaller than 15 mm².

14. The system of claim 1, wherein the Hall sensor and the temperature sensor are thermally-coupled.

15. The system of claim 1, wherein the controller is integrated into another electronic component.

16. The system of claim 2, wherein the temperature sensor is positioned in proximity to the Hall sensor within the coil.

17. The system of claim 2, including at least one additional temperature sensor to form a plurality of temperature sensors.

18. The system of claim 17, wherein the temperature correction is based on temperature sensing of at least two of the plurality of temperature sensors.

19. A mobile device comprising the system of claim 1.

20. The mobile device of claim 19, wherein the mobile device is a smartphone.
